(19) United States
(12) Patent Application Publication
(10) Pub. No.: US 2019/0360919 A1
(43) Pub. Date: Nov. 28, 2019

(54) DETECTION CHIP, DETECTION METHOD USING SAME, AND PREPARATION METHOD THEREFOR

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Yue GENG, Beijing (CN); Peizhi CAI, Beijing (CN); Fengchun PANG, Beijing (CN); Le GU, Beijing (CN); Chuncheng CHE, Beijing (CN); Hailin XUE, Beijing (CN); Xibin SHAO, Beijing (CN)

(21) Appl. No.: 16/331,625

(22) PCT Filed: Jul. 24, 2018
(86) PCT No.: PCT/CN2018/096863

§ 371 Date: Mar. 8, 2019

(30) Foreign Application Priority Data
Jul. 24, 2017 (CN) 201710608250.7

(51) Int. Cl. G01N 21/01; H01L 31/09

(52) U.S. Cl. CPC G01N 21/01; G01N 21/6486; H01L 31/09

(57) ABSTRACT

A detection chip, a detection method using the same and a manufacturing method thereof are provided. The detection chip includes: a detection baseplate including a first substrate and at least one photoresistor disposed on the first substrate; at least one cantilever beam configured to correspond to the at least one a photoresistor, wherein an orthographic projection of the cantilever beam on the detection baseplate is located within a region where the corresponding photoresistor is located, the cantilever beam has a free end that is separated from the photoresistor by a predetermined distance and that is movable relative to the photoresistor.

### CROSS REFERENCE TO RELATED APPLICATIONS

The present application is based upon International Application No. PCT/CN2018/096863, filed on Jul. 24, 2018, which is based upon and claims priority of Chinese patent application No. 201710608250.7, filed on Jul. 24, 2017, the entire disclosure of which is hereby incorporated by reference as a part of the present application.

### TECHNICAL FIELD

The present disclosure relates to the field of biomolecule detection and biochips, and more particularly to a detection chip and a detection method using the same and a manufacturing method thereof.

### BACKGROUND

The current mainstream method of biomolecule detection is detection of labeled signals. For example, gene sequencing is performed by different fluorophore modifications on various bases. When these bases are paired with gene fragments under test, the fluorophore is released. A type of the base can be determined by detecting color of the fluorescent by an optical system. Finally the sequence of the gene fragments under test can be obtained. The protein detection is also to label the protein molecule by means of fluorescent labeling or isotope labeling, and finally to determine the type and structure of the protein by detecting the signal of the labeled group.

It should be noted that the information disclosed in the Background section above is only for enhancement of understanding of the background of the present disclosure, and thus may include information that does not constitute prior art known to those of ordinary skill in the art.

### SUMMARY

The present disclosure provides a detection chip, a detecting method using the same and a manufacturing method thereof.

According to one aspect of the present disclosure, there is provided a detection chip, including: a detection baseplate, including a first substrate and at least one photoresistor disposed on the first substrate; and at least one cantilever beam configured to correspond to the at least one photoresistor, wherein an orthographic projection of the cantilever beam on the detection baseplate is located within a region where the corresponding photoresistor is located, and the cantilever beam has a free end that is spaced apart from the photoresistor by a predetermined distance and that is movable relative to the photoresistor.

In one embodiment, the detection chip further includes: a supporting layer on the first substrate, wherein the cantilever beam is connected to the first substrate through the supporting layer.

In one embodiment, the detection chip further includes a microelectromechanical system (MEMS) baseplate, wherein the MEMS baseplate is opposite to the detection baseplate, and the cantilever beam is disposed on the MEMS baseplate.

In one embodiment, the detection chip further includes a supporting member disposed on a surface of the MEMS baseplate away from the detection baseplate, wherein a side of the supporting member away from the detection baseplate is provided with a transparent cover, the MEMS baseplate, the supporting member and the transparent cover form a passage, and the transparent cover includes thereon a sample inlet and a sample outlet in communication with the passage.

In one embodiment, the material of the first substrate may be silicon or glass.

In one embodiment, the supporting member may contain silicon oxide, silicon nitride or a polymer.

In one embodiment, the detection chip further includes a wire electrically connected to the photoresistor.

In one embodiment, the free end is attached with a detection reagent.

In one embodiment, an orthographic projection of the cantilever beam on the detection baseplate is located within a region where the corresponding photoresistor is located

According to another aspect of the present disclosure, there is provided a detecting method using the detection chip as described above, the detecting method including the steps of: attaching a detection reagent for detecting a specific sample to a free end of the cantilever beam; injecting a medium containing a sample under test into the detection chip; irradiating light over the detection chip, recording a resistance value of the photoresistor, and comparing the resistance value with a resistance value of the photoresistorbefore medium containing the sample under test is injected and after the detection reagent for detecting the specific sample is attached; and determining a type of the sample under test based on the comparison result.

In one embodiment, the detection chip includes a photoresistor array and a corresponding cantilever beam array, the detection chip is divided into a plurality of detection regions, in different detection regions of the plurality of detection regions, the free ends of the cantilever beams are connected to different types of detection reagents for detecting different types of samples under test.

In one embodiment, after the free end of the cantilever beam is attached with a detection reagent for detecting a specific sample, the free end of the cantilever beam generates a first amount of curved deformation toward the corresponding photoresistor, and a resistance value of the corresponding photoresistor is recorded as a first resistance value.

In one embodiment, after a medium containing a sample under test is injected into the detection chip, if the cantilever beam attached with a detection reagent reacts with the sample under test, the cantilever beam generates a second amount of curved deformation toward the corresponding photoresistor, a resistance value of the corresponding photoresistor is recorded as a second resistance value, and the second resistance value is different from the first resistance value.

In one embodiment, according to the photoresistor having a change in the resistance value, a type of the detection reagent attached to the cantilever beam corresponding to the photoresistor is obtained, and a type of the sample under test is determined.

In one embodiment, the photoresistor in the photoresistor array may have a hexagonal cross section.

According to another aspect of the present disclosure, there is provided a manufacturing method of a detection chip, including:

preparing a first substrate;

forming at least one photoresistor on the first substrate; and

preparing at least one cantilever beam, wherein an orthographic projection of the cantilever beam on the first substrate is located within a region where the corresponding photoresistor is located, and

the cantilever beam has a free end that is spaced apart from the photoresistor by a predetermined distance and that is movable relative to the photoresistor.

In one embodiment, preparing at least one cantilever beam includes:

forming a supporting layer on the first substrate, the supporting layer being patterned and exposing the at least one photoresistor; and

forming the at least one cantilever beam on the supporting layer.

In one embodiment, forming the at least one cantilever beam on the supporting layer includes:

forming a first material layer;

patterning the first material layer to form a hollow pattern having the at least one cantilever beam; and

attaching the hollow pattern to the supporting layer.

In one embodiment, forming the at least one cantilever beam on the supporting layer includes:

forming a sacrifice layer covering the photoresistor;

forming the at least one cantilever beam on the sacrifice layer such that a first end of the cantilever beam is connected to the supporting layer, and a second end is located above the photoresistor; and

removing the sacrifice layer.

In one embodiment, the second end is formed as a free end of the cantilever beam.

In one embodiment, preparing at least one cantilever beam includes:

preparing a second substrate;

forming at least one cantilever beam on the second substrate; and

attaching the second substrate to the first substrate such that the second substrate is disposed between the at least one cantilever beam and the first substrate.

It should be understood that the above general description and the following detailed description are intended to be illustrative and not restrictive.

This section provides an overview of various implementations or examples of the techniques described in the present disclosure, and is not a comprehensive disclosure of the full scope or all features of the disclosed technology.

### BRIEF DESCRIPTION OF THE DRAWINGS

In order to more clearly illustrate the embodiments of the present disclosure or the technical solutions in the prior art, the drawings to be used in the embodiments or the description of the prior art will be briefly described below. Apparently, the drawings in the following description are only some embodiments of the present disclosure, and other drawings may be obtained according to these accompanying drawings by those skilled in the art without paying any inventive effort.

FIG. 1 is a schematic perspective view showing a structure of a detection chip according to an embodiment of the present disclosure.

FIG. 2 is a schematic cross-sectional view showing a structure of a detection chip according to an embodiment of the present disclosure.

FIG. 3 is a schematic view showing a structure of a cantilever beam of a detection chip after attached with a detection reagent, according to an embodiment of the present disclosure.

FIGS. 4A, 4B, and 4C are schematic diagrams showing a structure of a detection unit in a detection chip when perform detection, according to an embodiment of the present disclosure.

FIG. 5 illustrates a flow chart of a detection method using a detection chip according to an embodiment of the present disclosure.

FIG. 6 schematically illustrates a flow chart of a manufacturing method of a detection chip according to an embodiment of the present disclosure.

FIGS. 7A to 7C schematically illustrate cross-sectional views of a manufacturing method of a detection chip according to an embodiment of the present disclosure.

FIG. 8 schematically illustrates a cross-sectional view of a manufacturing method of a detection chip according to an embodiment of the present disclosure.

### DETAILED DESCRIPTION

It will be understood that when an element or a layer is referred to as “on” or “connected to” another element or layer, the element or the layer may be directly on another element or layer, directly connected to or bonded to another element or layer, or an intermediate element or intermediate layer may also be present. The term “and/or” as used herein includes any and all combinations of one or more of the associated listed items. In addition, it will be understood that the spatially relative terms are intended to encompass different orientations of the device in use or operation in addition to the orientations described in the drawings.

As used herein, the singular forms “a”, “an” and “the” are also intended to include plural forms unless the context clearly states otherwise. It will also be understood that when the terms “comprising” and/or “including” are used in this description, it means presence of the features, integers, steps, operations, elements, and/or components described, but does not exclude the presence or addition of one or more other features, integers, steps, operations, elements, components, and/or groups thereof.

Hereinafter, the present disclosure will be explained in detail with reference to the accompanying drawings.

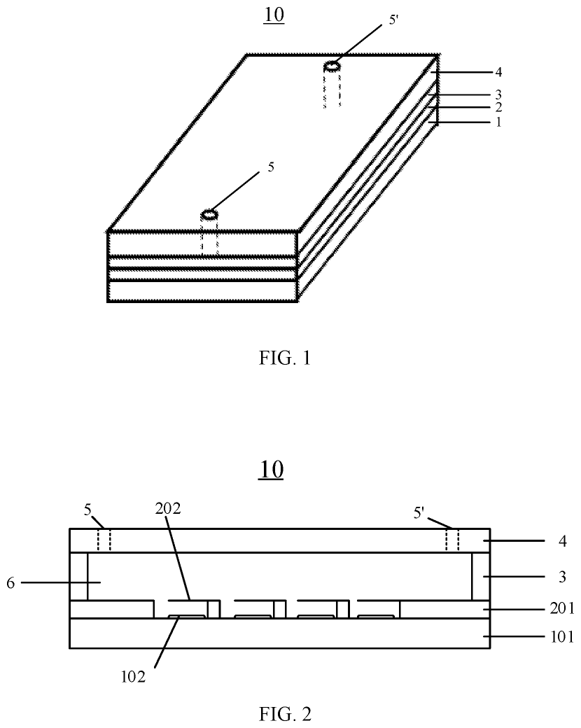

FIG. 1 is a schematic perspective view showing a structure of a detection chip 10 according to an embodiment of the present disclosure. FIG. 2 is a schematic cross-sectional view showing a structure of a detection chip 10 according to an embodiment of the present disclosure.

Referring to FIGS. 1 and 2, a detection chip 10 according to an embodiment of the present disclosure includes a detection baseplate 1 and a microelectromechanical system (MEMS) baseplate 2 disposed opposite each other.

The detection baseplate 1 includes a first substrate 101 and a photoresistor array 102 formed of an array of a plurality of photoresistors 102 on the first substrate 101. The material of the first substrate 101 may be silicon or glass, but is not limited thereto.

The photoresistor array 102 may be fabricated on silicon or glass by a MEMS fabrication process.

The MEMS baseplate 2 includes a second substrate 201 and a cantilever beam formed of an array of a plurality of cantilever beams 202 disposed on the second substrate 201.

Each cantilever beam 202 in the cantilever beam array is configured to correspond to a respective photoresistor 102 in the photoresistor array. In one embodiment, each cantilever beam 202 may be configured to correspond to each photoresistor 102 in a one-to-one correspondence. That is, one cantilever beam 202 may be disposed corresponding to one photoresistor 102, which together constitute one detection unit of the detection chip 10.

It should be understood that in the present embodiment, the detection chip 10 includes an array composed of a plurality of photoresistors 102 and a plurality of cantilever beams 202, but the present disclosure is not limited thereto. In other embodiments of the present disclosure, the number of the photoresistors and the cantilever beams may be arbitrarily selected according to specific needs. For example, the detection chip 10 may also include only one photoresistor 102 and one cantilever beam 202 corresponding to the photoresistor 102.

It should also be understood that in the present embodiment, the detection baseplate 1 and the MEMS baseplate 2 are illustrated as separate baseplates, however the present disclosure is not limited thereto, and in other embodiments of the present disclosure, the detection baseplate 1 and the MEMS baseplate 2 may be formed in one body. For example, in one embodiment, the cantilever beam 202 may be formed on the detection baseplate 1 such that the cantilever beam 202 is spaced apart from the photoresistor 102 by a predetermined distance by, for example, forming a supporting layer or the like on the detection baseplate 1.

Each cantilever beam 202 in the cantilever beam array includes a fixed end secured to the second substrate and a free end (i.e., the cantilever) 202f extending from the fixed end. The free end may be surface treated (or surface modified) to be attached with detection reagents such as enzymes, antigens, and the like.

In one embodiment, the detection chip 10 may include (e.g., be divided into) a plurality of detection regions. In different regions of the plurality of detection regions, the cantilever beams may be attached with different types of detection reagents. For example, in a first detection region, the same detection reagent is attached to the cantilever beams, and in a second detection region, a detection reagent different from the detection reagent in the first detection region is attached to the cantilever beams. Different types of detection reagents are used to detect different types of samples under test. Since the detection chip 10 is divided into a plurality of detection regions, each of the detection regions may include a separate sample inlet and a separate sample outlet.

The detection chip 10 further includes a supporting member 3 disposed on a surface of the MEMS baseplate 2 away from the detection baseplate 1, and a side of the supporting member 3 away from the detection baseplate 1 is provided with a transparent cover 4. The MEMS baseplate 2, the supporting member 3 and the transparent cover 4 may constitute a passage 6. A sample inlet 5 and a sample outlet 5′ in communication with the passage 6 are formed on the transparent cover 4.

A medium containing a sample under test may be injected into the passage 6 of the detection chip 10 through the sample inlet 5, flows in the passage 6 and flows out of the sample port 5′. In this embodiment, the medium containing the sample under test may be a solution, but the disclosure is not limited thereto, and the medium containing the sample under test may also be a medium of other states such as a suspension, an emulsion, a colloid, or the like, as long as it may flow through the passage 6 from the sample inlet 5 to the sample outlet 5′.

The supporting member 3 may be a stopper disposed around the periphery of the detection chip 10 for forming a passage 6 together with the MEMS baseplate 2 and the transparent cover 4, so that the medium containing the sample under test may enter through the sample inlet, and then flow in the passage 6, as shown in FIG. 2. The material of the supporting member 3 may be silicon oxide, silicon nitride or a polymer, but is not limited thereto.

The material of the transparent cover 4 may be a transparent material such as glass, polymer, or the like, and light such as infrared light, ultraviolet light, visible light, or the like may pass through the transparent cover 4. Specifically, a suitable transparent material may be selected to form the transparent cover 4 according to the spectral characteristics of the selected photoresistor.

The detection chip 10 may also include wires (not shown) that are electrically connected to each of the photoresistors 102 in the photoresistor array. The wires may be connected to a resistance measuring device, whereby the resistance of each of the photoresistors 102 may be detected.

The wires electrically connected to each of the photoresistors 102 may be formed by performing photolithography on metal, but the method of forming the wires is not limited thereto.

In an embodiment, the photoresistor 102 is configured to sense the signal intensity of light that is illuminated onto the photoresistor through the transparent cover 4 and convert it into a resistance signal. The resistance value of the photoresistor may be obtained by measuring the resistance signal by the resistance measuring device.

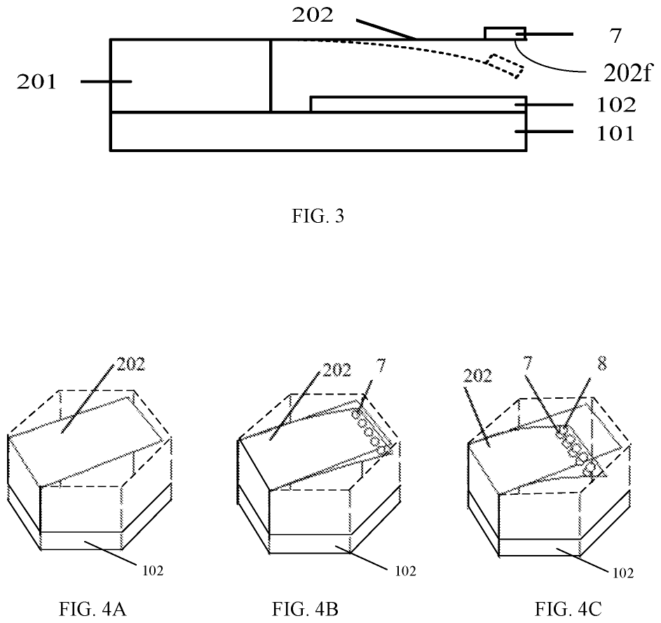

A detection method for determining the type (or structure) of a sample under test using the above-described detection chip will be described below with reference to FIGS. 3, 4a, 4b, and 4c and 5.

FIG. 3 is a schematic view showing a structure of a cantilever beam of a detection chip before and after attached with detection agent according to an embodiment of the present disclosure.

Referring to FIG. 3, a solid line in FIG. 3 shows the case where a cantilever beam 202 of the detection chip is not attached with a detection reagent. That is, the cantilever beam 202 is placed in a horizontal state. A broken line in FIG. 3 shows the case after a cantilever beam 202 of the detection chip is attached with a detection reagent 7. That is, the cantilever beam 202 bends toward the photoresistor 102 below.

FIGS. 4A, 4B, and 4C are schematic diagrams showing a structure of one detection unit in the detection chip when perform detection, according to an embodiment of the present disclosure. FIG. 5 illustrates a flow chart of a detection method using the detection chip according to an embodiment of the present disclosure.

Referring to FIG. 5, a detecting method using the detection chip described above according to an embodiment of the present disclosure includes the following steps. A detection reagent for detecting a specific sample is attached to each of the cantilever beams in the cantilever beam array (specifically, the detection reagent may be attached to the treated free end, for example, the end of the cantilever beam). A medium containing the sample under test is injected through the sample inlet 5 into the passage 6 of the detection chip 10. The transparent cover 4 is illuminated with light (either artificial light or natural light) and a resistance value of each photoresistor 102 is recorded. The recorded resistance value is compared with the resistance value of the photoresistor 102 before the medium containing the sample under test is injected. A type of the sample under test is determined according to the comparison result.

In one embodiment, the free ends of the respective cantilever beams 202 may be attached with different types of detection reagents, and different types of detection reagents may be used to detect different types of samples under test.

The cantilever beam array is used as a light shielding plate for the photoresistor array. When the corresponding cantilever beam 202 in the cantilever beam array is attached to the detection reagent 7, the corresponding cantilever beam 202 is bent toward the corresponding photoresistor 102, and then the resistance value of the corresponding photoresistor 102 is recorded as a first resistance value.

Specifically, as shown in FIG. 4A, in one detection unit of the detection chip, the cantilever beam 202 to which the detection reagent is not attached may partially shield the underlying photoresistor 102. In other embodiments, in one detection unit of the detection chip, the cantilever beam 202 to which the detection reagent is not attached may completely shield the underlying photoresistor 102.

However, after the free end of the cantilever beam 202 is attached with a detection reagent (such as an enzyme, an antigen, etc.) for detecting a specific biomolecule, the cantilever beam 202 generates a first amount of curved deformation downward toward the corresponding photoresistor 102, as shown in the FIG. 4B. In this case, the transparent cover 4 is irradiated with light, and a part of the corresponding photoresistor 102 receives the light, and the resistance value of the corresponding photoresistor 102 is recorded as the first resistance value.

Then, the medium containing the sample under test is injected into the passage 6 of the detection chip 10 through the sample inlet 5. The photoresistor 102 may be covered by a transparent film to avoid being affected by the medium containing the sample under test.

When a specific biological reaction of the sample under test with the biomolecule occurs on the corresponding cantilever beam 202 to which the detection reagent 7 is attached, the corresponding cantilever beam 202 will generate a second amount of curved deformation toward the corresponding photoresistor 102, and then the resistance value of the corresponding photoresistor is recorded as a second resistance value.

Specifically, as shown in FIG. 4C, when specific binding occurs between the detection reagent 7 on the free end of the cantilever beam 202 and the sample 8 under test (such as a substrate, an antibody, etc.) injected into the passage 6, the cantilever beam 202 will produce the second amount of curved deformation toward the corresponding photoresistor 102. In this case, the transparent cover 4 is irradiated with light, and the area of the light receiving portion of the corresponding photoresistor 102 is changed. At this time, the resistance value of the corresponding photoresistor 102 is recorded as the second resistance value. In this case, there is a difference between the first resistance value and the second resistance value. However, when no specific binding occurs between the detection reagent 7 on the free end of the cantilever beam 202 and the sample 8 under test injected into the passage 6, the cantilever beam 202 does not produce the second amount of curved deformation with respect to the corresponding photoresistor 102. At this time, there is no difference between the first resistance value and the second resistance value.

When there is a difference between the first resistance value and the second resistance value, the type of the sample under test may be determined. That is, according to the photoresistor having a change in the resistance value, the type of the detection reagent attached to the cantilever beam corresponding to the photoresistor can be obtained, thereby the type of the sample under test can be determined.

Before the resistance value of the corresponding photoresistor 102 is recorded as the second resistance value, the medium remaining in the detection chip 10 may be sucked by vacuuming to discharge the residual medium through the sample outlet 5′, so as to more precisely detect the deformation amount of the free end of the cantilever beam relative to the corresponding photoresistor after the sample under test is added, thereby determining the type of sample under test. For example, taking detection of a proteolytic enzyme as an example, the free end of the cantilever beam 202 is surface modified to attached with a substrate corresponding to a decomposition reaction with the enzyme. The free end of the cantilever beam 202 may be attached with a large amount of substrate protein molecules, such that the cantilever beam 202 is pressed down due to gravity to generate a first amount of curved deformation. Light is irradiated above the detection chip 10, and a first resistance value of the photoresistor 102 corresponding to the first amount of curved deformation is recorded.

Thereafter, the clastic enzyme medium to be detected is introduced into the detection chip 10 through the sample inlet 5, and after being placed for a while, the medium remaining in the detection chip 10 may be discharged from the sample outlet 5′ by vacuuming. If the clastic enzyme to be detected reacts with the substrate at the free end of the cantilever beam 202, the substrate protein molecules may breakdown, and the molecular weight of the detection reagent attached to the free end of the cantilever beam 202 becomes small, such that the deformation amount caused by depression due to gravity is decreased to a second deformation amount. A second resistance value of the photoresistor value 102 corresponding to the second deformation amount is recorded. In this case, there is a significant difference between the second resistance value and the first resistance value. Therefore, it may be determined that the clastic enzyme medium to be detected contains a proteolytic enzyme. It may be understood that for some samples under test, after chemical reaction with the detection reagent occurs, a new substance is generated at the free end of the cantilever beam, so that the molecular weight on the free end of the cantilever beam becomes larger, such that the deformation amount caused by depression due to gravity is increased to a second deformation amount. A second resistance value of the photoresistor value 102 corresponding to the second deformation amount is recorded. In this case, there is a significant difference between the second resistance value and the first resistance value. By the same token, it can also determine the type of sample under test.

If the clastic enzyme to be detected does not have specific interaction with the substrate at the free end of the cantilever beam 202, the deformation amount of the free end of the cantilever beam 202 caused by depression due to gravity does not change, that is, there is no difference between the second resistance value and the first resistance value. Therefore, it may be determined that the proteolytic enzyme medium is not contained in the clastic enzyme medium to be detected.

Further, the photoresistor 102 in the photoresistor array has a hexagonal cross section, but is not limited thereto, and it may be designed in various shapes. The photoresistors 102 in the photoresistor array need not be closely packed, and a certain gap may be left between them to facilitate plotting before detection. In addition, the size of each of the photoresistors 102 (i.e., the distance between two points farthest from each other in the cross section) may be several tens of micrometers to several hundreds of micrometers. The distance between the photoresistors 102 may also be several tens of micrometers to several hundreds of micrometers. That is, the magnitude of the distance between the photoresistors 102 is the same as the magnitude of the size of each of the photoresistors. For example, when the size of each of the photoresistors 102 is several tens of micrometers, the distance between the photoresistors 102 is correspondingly several tens of micrometers. However, those skilled in the art may set the size of the appropriate photoresistor 102 and the distance between the photoresistors 102 according to actual needs, and the disclosure is not limited to the above.

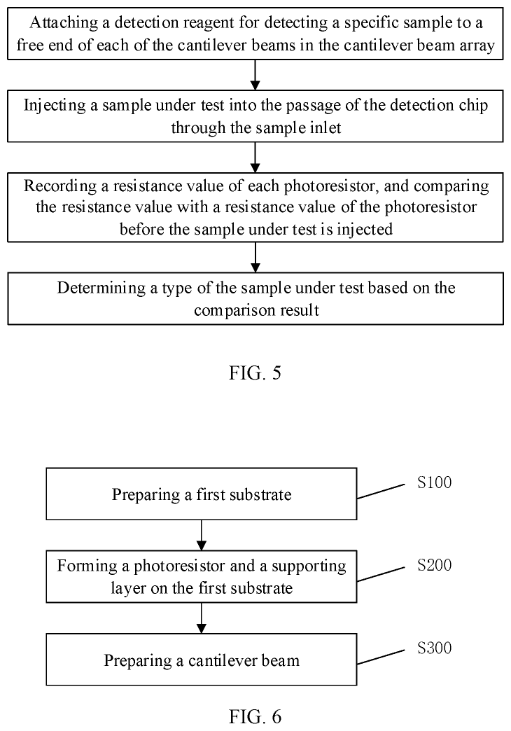

FIG. 6 schematically illustrates a flow chart of a manufacturing method of a detection chip according to an embodiment of the present disclosure.

Referring to FIG. 6, a manufacturing method of a detection chip according to an embodiment of the present disclosure may include: a step S100 of preparing a first substrate; a step S200 of forming a photoresistor on the first substrate; and a step S300 of preparing a cantilever beam.

In the present disclosure, an orthographic projection of the cantilever beam on the first substrate is located within a region where the corresponding photoresistor is located. The cantilever beam has a free end, and the free end is spaced from the photoresistor at a predetermined distance and is movable relative to the photoresistor.

According to the present embodiment, the detection chip as described in the foregoing embodiments may be manufactured.

The details of the respective components in the manufacturing method of the present embodiment have been described with reference to the foregoing embodiments, and thus will not be described again herein.

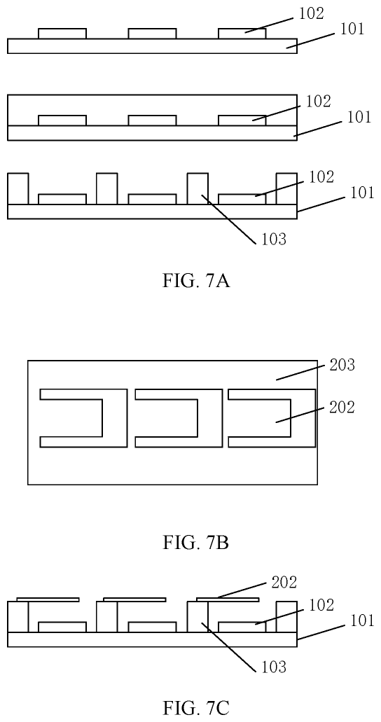

FIGS. 7A to 7C schematically illustrate cross-sectional views of a manufacturing method of a detection chip according to an embodiment of the present disclosure.

Referring to FIG. 7A, a photoresistor array 102 is formed on a first substrate 101, and as described in the foregoing embodiments, the photoresistor array 102 may include at least one photoresistor. Then, a supporting layer is formed on the surface on which the photoresistor array 102 is formed and patterned to form a patterned supporting layer 103. The patterned supporting layer exposes the photoresistor array 102.

Next, as shown in FIG. 7B, a first material layer 203 is prepared and the first material layer 203 is patterned to form a hollow pattern having at least one cantilever beam 202.

Next, as shown in FIG. 7C, the hollow pattern is attached to the first substrate 101 such that the at least one cantilever beam 202 is configured to correspond to the at least one photoresistor in the photoresistor array 102.

It should be understood that in the embodiment illustrated in FIGS. 7A to 7C, it is shown that the supporting layer 103 is formed on the detection baseplate, and the cantilever beam 202 is connected to the first substrate 101 through the supporting layer 103. However, the present disclosure is not limited thereto, and other structures may be used instead of the supporting layer 103. For example, as in the embodiment shown in FIG. 2, a second substrate 201 may be formed, a cantilever beam 202 is formed on the second substrate 201, and then the second substrate is attached to the first substrate, such that the second substrate 201 is located between the at least one cantilever beam 202 and the first substrate 101.

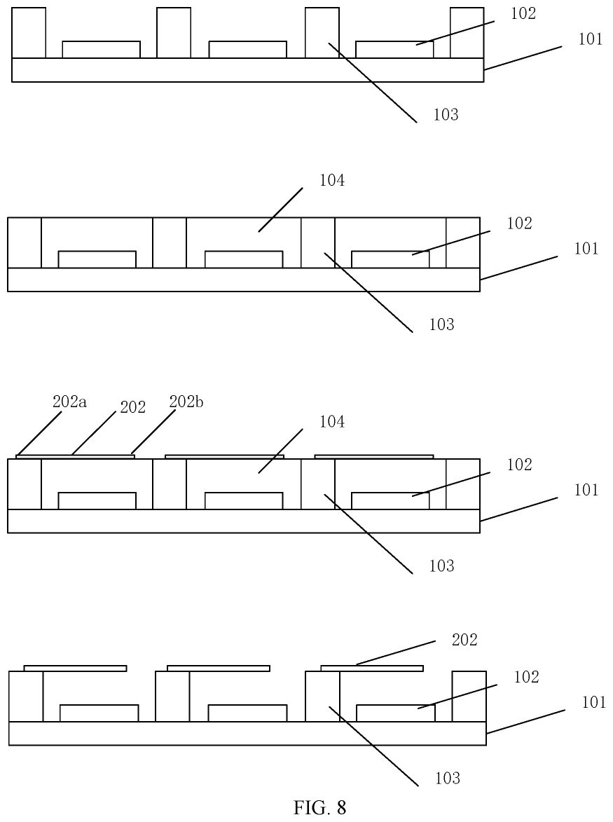

FIG. 8 schematically illustrates a cross-sectional view of a manufacturing method of a detection chip according to an embodiment of the present disclosure.

Referring to FIG. 8, a photoresistor array 102 is formed on a first substrate 101, and the photoresistor array 102 may include at least one photoresistor as described in the foregoing embodiments. Then, a supporting layer is formed on the surface on which the photoresistor array 102 is formed and patterned to form a patterned supporting layer 103. The patterned supporting layer exposes the photoresistor array 102.

Next, a sacrifice layer 104 covering the photoresistor array 102 is formed.

Next, the at least one cantilever beam 202 is formed on the sacrifice layer 104 such that the first end 202a of the cantilever beam 202 is connected to the supporting layer 103, and the second end 202b is located above the photoresistor array 202. It should be understood that the cantilever beam 202 may be first deposited with a layer of forming material and then patterned, or may be directly deposited into a desired pattern using a mask.

Next, the sacrifice layer 104 is removed, thereby completing the detection chip of the present disclosure. In the present disclosure, the sacrifice layer 104 may be removed using a process such as wet etching, but the present disclosure is not limited thereto. After the sacrifice layer 104 is removed, the second end 202b is suspended above the photoresistor 102 to form a free end of the cantilever beam.

The various biomolecules such as bases, antigens, etc., used in the embodiments of the present disclosure do not need special labeling, which can greatly reduce the cost of the reagent. The preparation technology of such detection chip is mature, and can be realized by MEMS manufacturing technology. Accuracy of detection of photoresistor optical signals can be high, thereby it can improve the detection accuracy

The foregoing description of the specific exemplary embodiments of the present disclosure has been provided with reference to the accompanying drawings. The exemplary embodiments are not intended to be exhaustive or to limit the present disclosure to the precise form disclosed. It is apparent that many modifications and changes may be made by those skilled in the art. Therefore, the scope of the present disclosure is not intended to be limited to the foregoing embodiments, but is intended to be defined by the claims and their equivalents.

1. A detection chip, comprising:
a detection baseplate, comprising a first substrate and at least one photoresistor disposed on the first substrate; and
at least one cantilever beam configured to correspond to the at least one photoresistor,
wherein an orthographic projection of the cantilever beam on the detection baseplate is located within a region where corresponding photoresistor is located, and
the cantilever beam has a free end that is spaced apart from the photoresistor by a predetermined distance and that is movable relative to the photoresistor.

2. The detection chip according to claim 1, further comprising:
a supporting layer on the first substrate, wherein the cantilever beam is connected to the first substrate through the supporting layer.

3. The detection chip of claim 1, further comprising a microelectromechanical system (MEMS) baseplate, wherein the MEMS baseplate is opposite to the detection baseplate, and the cantilever beam is disposed on the MEMS baseplate.

4. The detection chip according to claim 3, further comprising a supporting member disposed on a surface of the MEMS baseplate away from the detection baseplate, wherein a transparent cover is disposed at a side of the supporting member away from the detection baseplate, a passage is formed by the MEMS baseplate, the supporting member and the transparent cover, and the transparent cover comprises thereon a sample inlet and a sample outlet in communication with the passage.

5. The detection chip according to claim 1, wherein the first substrate comprises silicon or glass.

6. The detection chip according to claim 4, wherein the supporting member comprises silicon oxide, silicon nitride or a polymer.

7. The detection chip according to claim 1, further comprising a wire electrically connected to the photoresistor.

8. The detection chip according to claim 2, wherein the free end is attached with a detection reagent.

9. A detecting method using the detection chip according to claim 1, the detecting method comprising the steps of:
attaching a detection reagent for detecting a specific sample to the free end of the cantilever beam;
irradiating light over the detection chip, and recording a first resistance value of the photoresistor;
injecting a medium containing a sample under test into the detection chip;
irradiating the light over the detection chip, recording a second resistance value of the photoresistor, and comparing the second resistance value with the first resistance value of the photoresistor; and
determining a type of the sample under test based on a comparison result.

10. The detecting method according to claim 9, wherein the detection chip comprises a photoresistor array and a corresponding cantilever beam array, the detection chip comprises a plurality of detection regions, in different detection regions of the plurality of detection regions, the free ends of the cantilever beams are connected to different types of detection reagents for detecting different types of samples under test.

11. The detecting method according to claim 9, wherein after the cantilever beam is attached with the detection reagent for detecting the specific sample, the free end of the cantilever beam generates a first amount of curved deformation toward the corresponding photoresistor, and a resistance value of the corresponding photoresistor is recorded as the first resistance value.

12. The detecting method according to claim 11, wherein after a solution containing a sample under test is injected into the detection chip, when the cantilever beam attached with a detection reagent reacts with the sample under test, the cantilever beam generates a second amount of curved deformation toward the corresponding photoresistor, a resistance value of the corresponding photoresistor is recorded as the second resistance value, and the second resistance value is different from the first resistance value.

13. The detecting method according to claim 12, wherein according to the photoresistor having a change in the resistance value, a type of the detection reagent attached to the cantilever beam corresponding to the photoresistor is obtained, and a type of the sample under test is determined.

14. The detecting method according to claim 9, wherein the photoresistor in the photoresistor array has a hexagonal cross section.

15. A manufacturing method of a detection chip, comprising:
preparing a first substrate;
forming at least one photoresistor on the first substrate; and
preparing at least one cantilever beam, wherein an orthographic projection of the cantilever beam on the first substrate is located within a region where corresponding photoresistor is located, and
the cantilever beam has a free end that is spaced apart from the photoresistor by a predetermined distance and that is movable relative to the photoresistor.

16. The method of claim 15, wherein preparing at least one cantilever beam comprises:
forming a supporting layer on the first substrate, the supporting layer being patterned and exposing the at least one photoresistor; and
forming the at least one cantilever beam on the supporting layer.

17. The method of claim 16, wherein forming the at least one cantilever beam on the supporting layer comprises:
forming a first material layer;
patterning the first material layer to form a hollow pattern having the at least one cantilever beam; and
attaching the hollow pattern to the supporting layer.

18. The method of claim 16, wherein forming the at least one cantilever beam on the supporting layer comprises:
forming a sacrifice layer covering the photoresistor;
forming the at least one cantilever beam on the sacrifice layer such that a first end of the cantilever beam is connected to the supporting layer, and a second end is located above the photoresistor; and
removing the sacrifice layer.

19. The method of claim 18, wherein the second end is formed as the free end of the cantilever beam.

20. The method of claim 15, wherein preparing at least one cantilever beam comprises:
preparing a second substrate;
forming at least one cantilever beam on the second substrate; and
attaching the second substrate to the first substrate such that the second substrate is disposed between the at least one cantilever beam and the first substrate.
